(19) United States
(12) Patent Application Publication
(10) Pub. No.: US 2008/0013579 A1
(43) Pub. Date: Jan. 17, 2008

(54) Buried-heterostructure semiconductor laser

(75) Inventors: Manabu Matsuda, Kawasaki (JP); Tsuyoshi Yamamoto, Kawasaki (JP); Kan Takada, Kawasaki (JP)

Correspondence Address: KRATZ, QUINTOS & HANSON, LLP, 1420 K Street, N.W., Suite 400, WASHINGTON, DC, 20005, US

(73) Assignee: FUJITSU LIMITED, Kawasaki (JP)

(21) Appl. No.: 11/365,821

(22) Filed: Mar. 2, 2006

(30) Foreign Application Priority Data
Oct. 3, 2005 (JP) 2005-290112

(51) Int. Cl. H01S 5/00; H01S 3/04

(52) U.S. Cl. 372/43.01

(57) ABSTRACT

A 1.3-μm wavelength band buried-heterostructure semiconductor laser includes a semiconductor substrate, a multiple quantum well active layer including quantum well layers and barrier layers, a buried layer in contact with side faces of the multiple quantum well active layer, wherein the barrier layers are made from AlGaInAsP or AlGaInAs, and an Al composition of the barrier layers is 0.275 or less.

### CROSS REFERENCE TO RELATED APPLICATIONS

This application is based on and hereby claims priority to Japanese Application No. 2005-290112 filed on Oct. 3, 2005 in Japan, the contents of which are hereby incorporated by reference.

### BACKGROUND OF THE INVENTION

1. Field of the Invention

The present invention relates to a buried-heterostructure semiconductor laser (an optical semiconductor device) serving as a light source for optical fiber transmission.

2. Description of the Related Art

In accordance with the recent increase in demand for Internet, efforts have been made to achieve ultrafast large-capacity optical communication/optical transmission.

In particular, for the purpose of usage in Datacom (Ethernet), demand has arisen for an uncooled semiconductor laser capable of direct modulation at 10 Gb/s or faster. As a substitute for an GaInAsP group material that has conventionally been used as a light source for Telecom, a semiconductor laser that is made from an AlGaInAs-group material and that has a multiple quantum well active layer is expected to play the role of the above uncooled semiconductor laser capable of direct modulation at 10 Gb/s or faster.

Generally, a semiconductor laser that outputs more intensive light has a larger relaxation oscillation frequency. As a consequence, the semiconductor laser is capable of direct modulation for a broader band and thereby can realize modulation at a high-speed bit rate.

A semiconductor laser including a multiple quantum well active layer made from an AlGaInAs-group material has a quantum well layer in which the well on the conduction band side (electron side) is 150 meV in depth, which is more than about two times as large as that of a GaInAsP-group semiconductor laser. For this reason, such an AlGaInAs-group semiconductor can inhibit overflow of electrons (hot carriers) when operating at high temperature and can thereby obtain sufficient light output over a wide temperature range. In particular, the semiconductor can carry out modulation at a high-speed bit rate even when operating at high temperature.

For such an AlGaInAs-group semiconductor laser, engineers have mainly developed a semiconductor laser 100 having a ridge-waveguide structure as shown in FIG. 9 because, if a buried-heterostructure semiconductor laser (see FIG. 1) used for Telecom has a multiple quantum well active layer made from an AlGaInAs-group material included, the surfaces containing Al are exposed to the both sides of the mesa structure and are oxidized in the event of re-growing of a buried layer after the formation of the mesa structure including a multiple quantum well active layer so that it is difficult to eliminate adverse effects caused by the oxidization.

Meanwhile, the ridge-waveguide semiconductor laser 100 generally has an oscillation threshold value not less than 20 mA, which is higher than that (generally 5-8 mA) of a buried-heterostructure semiconductor laser, and therefore consumes more electric power. Since the relaxation oscillation frequency depends on the volume of the active layer, a ridge-waveguide semiconductor laser, which is larger in the active-layer volume than a buried-heterostructure semiconductor laser, cannot obtain a large relaxation oscillation frequency.

Recent progress in studies makes it possible to bury the surfaces containing Al by growing a buried layer.

For example, an AlGaInAs-group quantum well laser which is buried by InP is disclosed in Bo Chen et al. “A Novel 1.3-μm High T0 AlGaInAs/InP Strained-Compensated Multi-Quantum Well Complex-Coupled Distributed Feedback Laser Diode” Japanese Journal of Applied Physics Vol. 38 (1999) pp. 5096-5100. In this reference, the barrier layer is made from AlGaInAs whose compositional wavelength is 1050 nm.

Further, Japanese Patent No. 2812273 discloses that the mesa structure including an AlGaInAs-group active layer is wrapped by a material having a wide band-gap to prevent electrons from leaking into the InP buried layer. However, in practice, it is very difficult to conduct a crystal growth of a material, such as AlInAs, in the form described in the publication.

### SUMMARY OF THE INVENTION

In order to obtain better advantages caused by largeness in depth of the well on the conduction band side (electron side) in an AlGaInAs-group semiconductor laser, engineers have presumed that it has been preferable to make the compositional wavelength of the barrier layer shorter.

As a solution, Inventors designed (a prototype of) a 1.3-μm wavelength band buried-heterostructure semiconductor laser (with the emission light wavelength of 1260-1340 nm) including a multiple quantum well active layer made from an AlGaInAs-group material and a barrier layer whose compositional wavelength is shorter than 1050 nm.

Specifically, the buried-heterostructure semiconductor laser is formed by stacking a multiple quantum well active layer which is formed by stacking an undoped AlGaInAs quantum well layer (respectively having a compositional wavelength of 1000 nm and having thickness of 6 nm, for example) and an undoped AlGaInAs barrier layer (having a compositional wavelength of 1000 nm and a thickness of 10 nm, for example), ten times alternately, on an n-doped InP substrate and stacking undoped AlGaInAs light guide layers (respectively having a thickness of 20 nm, for example) upward and downward of the multiple quantum well active layer to form a mesa structure including the quantum well active layer and the light guide layer (the width of these layers are assumed to be 1.2 μm) and subsequently by burying the mesa structure with a p-doped InP current blocking layer and an n-doped Inp current blocking layer and stacking a p-doped InP cladding layer and a p-doped GaInAs contact layer on the n-doped InP current blocking layer. In addition, a p-electrode and an n-electrode are formed on the top and the bottom of the semiconductor laser, respectively (see FIG. 1, for example) The result of measuring characteristic of the above AlGaInAs-group buried-heterostructure semiconductor laser finds that the semiconductor laser can reduce deterioration of light output with respect to drive current at room temperature even when the semiconductor laser is operating at high temperature (85° C. or higher, for example) as compared with a conventional GaInAsP-group buried-heterostructure semiconductor laser, and exhibits an oscillation threshold value roughly the same as that (7-8 mA, for example) of a conventional GaInAsP-group buried-heterostructure semiconductor laser.

However, the comparison of light output characteristics with respect to drive current at room temperature indicates that, as shown in FIG. 10, an AlGaInAs-group buried-heterostructure semiconductor laser reduces the proportion of increase in light output with respect to the drive current in accordance with increase in the drive current while a conventional GaInAsP-group buried-heterostructure semiconductor has a light output characteristic that linearly increases in proportion to increase in drive current.

In other words, the above-described AlGaInAs-group buried-heterostructure semiconductor laser has a barrier layer made from AlGaInAs whose compositional wavelength is 1000 nm, but such a structure results in the presence of a notch in the energy level of the electron side (the conduction band side) between the barrier layer and the InP buried layer, as shown in FIG. 11.

In particular, the energy level (point C) of the bottom of the notch is lower than that (point A) of the barrier layer as shown in FIG. 12. Further, the difference between the energy level (point A) of the barrier layer and that (point B) of the apex of the notch is 35 meV, which is lower than the barrier height 2 kT=52 meV (where k is Boltzmann constant and T is absolute temperature) over which electrons can easily jump. For this reason, the notch plays a role similar to a channel of 2-dimensional electron gas used for HEMT, so that electrons leaks through the notch but are not effectively flown into the quantum well. As a result, it was found that the light output deteriorates in accordance with increase in drive current as described above.

With the foregoing problems in view, the object of the present invention is to provide a 1.3-μm wavelength band buried-heterostructure semiconductor laser which prevents light output from deteriorating in accordance with increase in drive current.

For this purpose, as a first generic feature, there is provided a 1.3-μm wavelength band buried-heterostructure semiconductor laser, comprising: a semiconductor substrate; a multiple quantum well active layer including quantum well layers and barrier layers; and a buried layer in contact with side faces of said multiple quantum well active layer, wherein said barrier layers are made from AlGaInAsP or AlGaInAs, and an Al composition of said barrier layers is 0.275 or less.

Advantageously, it is possible for the 1.3-μm wavelength band buried-heterostructure semiconductor laser of the present invention to prevent light output from deteriorating in accordance with increase in drive current.

Other objects and further features of the present invention will be apparent from the following detailed description when read in conjunction with the accompanying drawings.

### BRIEF DESCRIPTION OF THE DRAWINGS

FIG. 1 is a perspective view schematically showing a buried-heterostructure semiconductor laser according to a first embodiment of the present invention;

FIG. 2 is a graph showing variations in energy level of a barrier layer, the apex of a notch, the bottom of the notch and a buried layer of the buried-heterostructure semiconductor laser of FIG. 1 if a compositional wavelength of the barrier layer is varied;

FIG. 3 is a graph showing variations of energy level differences between the barrier layer and the apex of the notch, between the barrier layer and the bottom of the notch, and between the apex and the bottom of the notch of the buried-heterostructure semiconductor laser of FIG. 1 if a compositional wavelength of the barrier layer is varied;

FIG. 4 is a graph showing energy levels of the barrier layer, the apex and the bottom of the notch, and the buried layer of the buried-heterostructure semiconductor laser of FIG. 1 if a compositional wavelength of the barrier layer of the buried-heterostructure semiconductor laser is set to be 1045 nm;

FIG. 5 is a graph showing energy levels of the barrier layer, the apex and the bottom of the notch, and the buried layer of the buried-heterostructure semiconductor laser of FIG. 1 if a compositional wavelength of the barrier layer of the buried-heterostructure semiconductor laser is set to be 1070 nm;

FIG. 6 is a graph showing an effect of the buried-heterostructure semiconductor laser of FIG. 1;

FIG. 7 is a perspective view schematically showing a buried-heterostructure semiconductor laser according to a second embodiment of the present invention;

FIG. 8 is a perspective view schematically showing a buried-heterostructure semiconductor laser according to a third embodiment of the present invention;

FIG. 9 is a perspective view schematically showing a conventional ridge-waveguide semiconductor laser;

FIG. 10 is a graph showing problems of AlGaInAs group buried-heterostructure semiconductor lasers;

FIG. 11 is a graph showing problems of AlGaInA group buried-heterostructure semiconductor lasers; and

FIG. 12 is a graph showing problems of AlGaInAs group buried-heterostructure semiconductor lasers and showing energy levels of a barrier layer, the apex and the bottom of a notch, and a buried layer if a compositional wavelength of the barrier layer is set to be 1000 nm.

### DESCRIPTION OF THE PREFERRED EMBODIMENTS

Various preferred embodiments of buried-heterostructure semiconductor lasers of the present invention will now be described with reference to the accompanying drawings.

### (a) First Embodiment

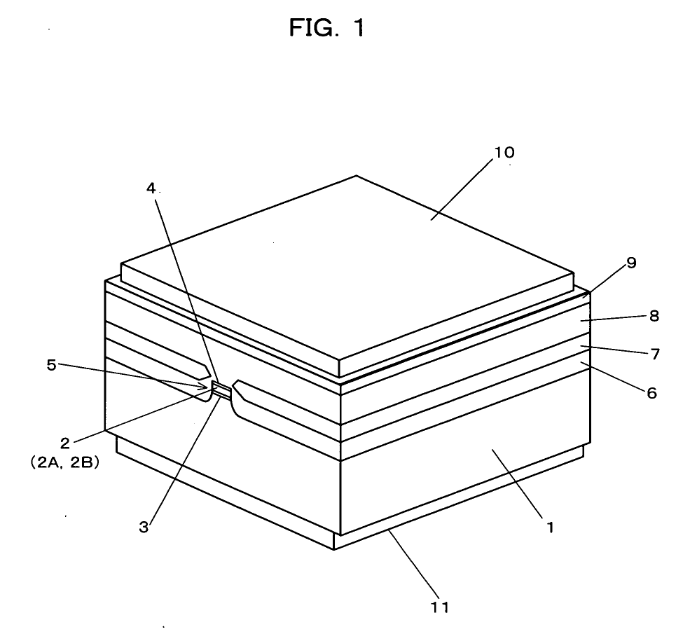

First of all, description will now be made in relation to a buried-heterostructure semiconductor laser according to the first embodiment with reference to FIGS. 1-6.

The buried-heterostructure semiconductor laser of the first embodiment is a 1.3-μm wavelength band buried-heterostructure semiconductor laser (with the emission light wavelength of 1260-1340 nm), and includes an n-doped InP substrate (a semiconductor substrate) 1, a multiple quantum well active layer 2 which is formed by stacking an undoped AlGaInAs quantum well layer 2A (having a thickness of 6 nm, for example) and an undoped AlGaInAs barrier layer 2B (having a thickness of 10 nm, for example), ten times alternately, and undoped AlGaInAs light guide layers 3 and 4 (respectively having a thickness of 20 nm, for example) which are stacked upward and downward of the multiple quantum well active layer 2, as exemplified in FIG. 1.

In the buried-heterostructure semiconductor laser of the present embodiment, a mesa structure 5 which includes the multiple quantum well active layer 2 and the light guide layers 3 and 4 is formed as shown in FIG. 1 (which assumes that the width of the multiple quantum well active layer and the light guide layers is 1.2 μm). A p-doped InP current blocking layer (an InP buried layer) 6 and an n-doped InP current blocking layer (an InP buried layer) 7 are formed on both sides of the mesa structure 5 and on the n-doped InP substrate 1 so as to be in contact with the sides of the multiple quantum well active layer 2 and the light guide layers 3 and 4 that form the mesa structure 5 and also so as to bury the mesa structure. On the p-doped InP current blocking layer 6 and the n-doped InP current blocking layer (an InP buried layer) 7, a p-doped InP cladding layer 8, and a p-doped GaInAs contact layer 9 are sequentially formed, so that the buried structure is a pnpn thyristor structure serving as a current blocking structure.

Further, a p-electrode 10 and an n-electrode are formed on the top and the bottom of the buried-heterostructure semiconductor laser, respectively.

Alternatively, a number of p-doped GaInAsP layers may be inserted between the p-doped InP cladding layer 8 and the p-doped GaInAs contact layer 9. Further alternatively, the buried-heterostructure semiconductor laser may include a single AlGaInAs light guide layer formed upward or downward of the multiple quantum well active layer 2.

If the barrier layers 2B and the light guide layers 3 and 4 are made from a semiconductor material (here, AlGaInAs) including Al (Aluminum), the energy levels of the conduction band side (the electron side) of the barrier layers 2B and the light guide layers 3 and 4 rise. For this reason, the relationship between the energy level of the buried layers (here, the InP buried layers) 6 and 7 in contact with the sides of these layers 2B, 3 and 4 and that of the conduction band side (the electron side) of these layers 2B, 3 and 4 is in question. In other words, it was found that the presence of a notch between energy levels on the electron side (conduction band side) of the barrier layers 2B and the InP buried layers 6 and 7 described above deteriorates the light output in accordance with increase in drive current.

As a solution, the buried-heterostructure semiconductor laser of the present embodiment sets the compositional wavelength of the barrier layers 2B and the light guide layers 3 and 4 (the compositional wavelength on the edge of the conduction band) to be 1070 nm or longer. In the illustrated example, the compositional wavelength of the barrier layers 2B and the light guide layers 3 and 4 is set to be 1100 nm.

The compositional wavelength of the barrier layers 2B is not necessarily set to be the same as that of the light guide layers 3 and 4. However, the compositional wavelength of the light guide layers 3 and 4 has to be set shorter than that of the barrier layers 2B.

In order to set the compositional wavelengths of the barrier layers 2B and the light guide layers 3 and 4 to be 1070 nm or longer, the buried-heterostructure semiconductor laser of the present embodiment sets the Al composition (the Al composition ratio) to be 0.275 or less. The reason for this setting will now be described below.

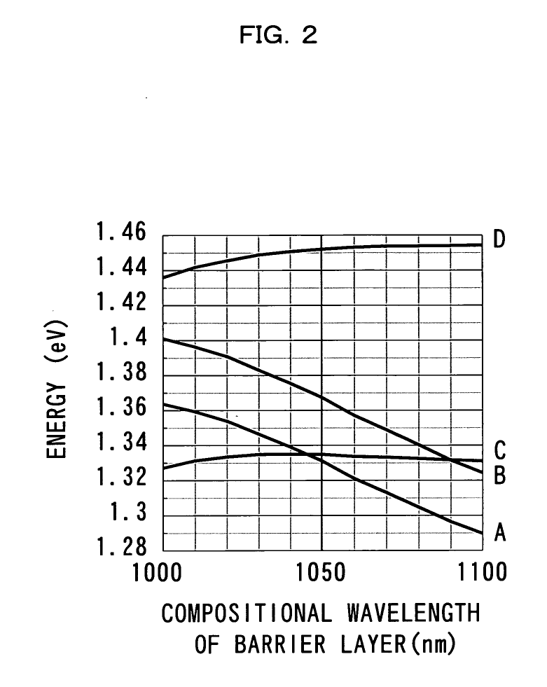

Here, FIG. 2 shows the results of simulation of energy levels of conduction band (the electron sides) of the barrier layers 2B (represented by solid line A in the drawing), the apex (represented by solid line B in the drawing) and the bottom (represented by solid line C in the drawing) of the notch, and the InP buried layer 6 and 7 (represented by solid line D in the drawing) when the compositional wavelength of the barrier layers 2B varies from 1000 nm to 1100 nm.

As shown by solid lines A and C in FIG. 2, when the compositional wavelength of the barrier layers 2B is shorter than 1045 nm, the energy level (solid line C) of the notch bottom is lower than that (solid line A) of the barrier layers 2B; but when the compositional wavelength of the barrier layers 2B is 1045 nm or longer, the energy level (solid line C) of the notch bottom is higher than that (solid line A) of the barrier layers 2B.

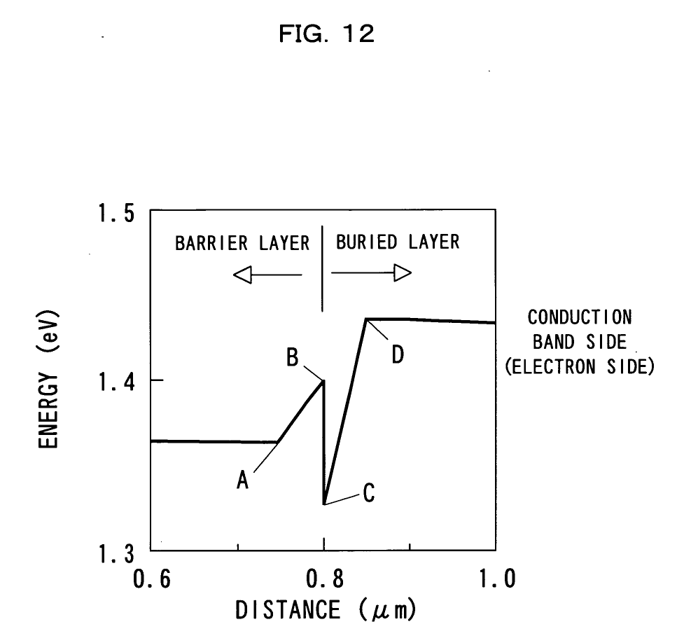

As described above, for example, the relationship shown in FIG. 12 is established among the energy level (point A) of the barrier layers 2B, the energy level (point B) of the apex and the energy level (point C) of the bottom of the notch, and the energy level (point D) of the InP buried layers 6 and 7 when the compositional wavelength of the barrier layers 2B is 1000 nm. In particular, the energy level (point C) of the notch bottom is lower than that (point A) of the barrier layers 2B. On the other hand, when the compositional wavelength of the barrier layers 2B is 1045 nm, the energy level (point A) of the barrier layers 2B, the energy level (point B) of the notch apex and the energy level (point C) of the notch bottom, and the energy level (point D) of the InP buried layers 6 and 7 establishes the relationship shown in FIG. 4. In particular, the energy level (point C) of the notch bottom is higher than that (point A) of the barrier layers 2B.

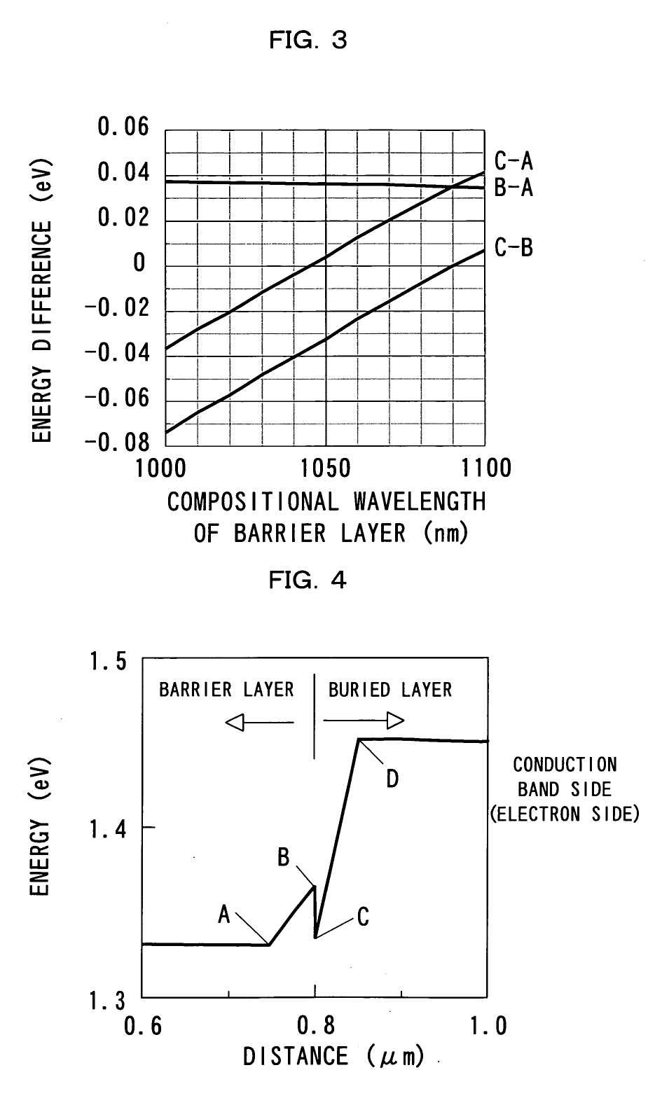

FIG. 3 shows the difference (solid line C-A in the drawing) between the energy level of the notch bottom and that of the barrier layers 2B, the difference (solid line C-B in the drawing) between the energy level of the notch bottom and that of the notch apex, and the difference (solid line B-A in the drawing) between the energy level of the notch apex and that of the barrier layers 2B.

As shown by solid line B-A in FIG. 3, the difference (solid line B-A in the drawing) between the energy level of the notch apex and that of the barrier layers 2B is stable at about 35 meV, but, as solid lines C-B and B-A in FIG. 3 show, if the compositional wavelength of the barrier layers 2B is longer than 1070 nm, the depth of the notch (i.e., the difference of energy levels of the notch apex and the notch bottom: solid line C-B) is half the height of the notch (i.e., the difference of energy levels of the notch apex and the barrier layers 2B: solid line B-A) or less.

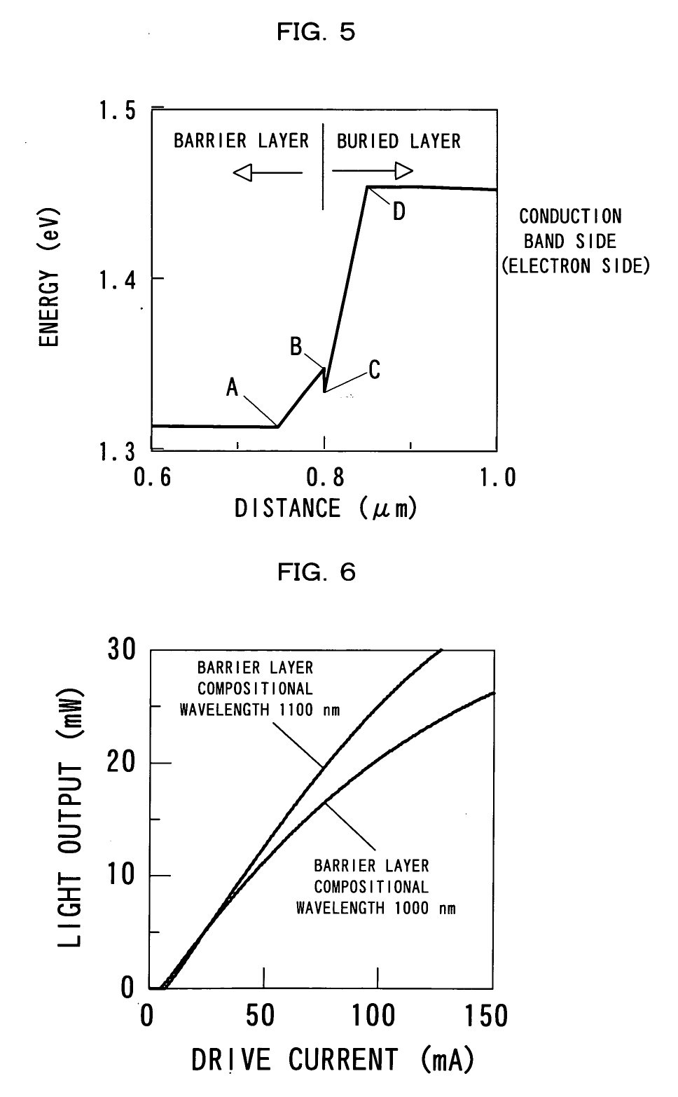

For example, when the compositional wavelength of the barrier layer 2B is 1070 nm, the energy level (point A) of the barrier layers 2B, that (point B) of the notch apex, that (point C) of the notch bottom, and that (point D) of the InP layers 6 and 7 establish the relationship shown in FIG. 5. In particular, the notch depth becomes not more than half of the notch height. Further, it is preferable that the energy level (point C) of the notch bottom is closer to the energy level (point B) of the notch apex than that (point A) of the barrier layers 2B.

It has been found very difficult to localize electrons inside the notch when the notch depth becomes not more than half of the notch height and the notch no longer functions as a channel, so that electrons can be efficiently implanted into the quantum wells.

For this reason, the buried-heterostructure semiconductor laser of the present embodiment sets the compositional wavelength of the barrier layers 2B (the compositional wavelength of the edge of the conduction band of the barrier layers) to be 1070 nm or longer.

In order to set the compositional wavelength of the barrier layers 2B to be 1070 nm or longer, the buried-heterostructure semiconductor laser of the present embodiment sets the Al composition of the barrier layers 2B to be 0.275 or less.

Meanwhile, since the buried-heterostructure semiconductor laser of the present embodiment is a 1.3-μm wavelength band semiconductor laser (with an emission light wavelength of room temperature of 1260-1310 nm, specifically 1260-1340 nm if considering a shift to the longer-wavelength side when operating at high temperature), the compositional wavelength of the barrier layers 2B (the compositional wavelength of the edge of the conduction band side) is set to be 1310 nm or shorter (to be 1340 nm or shorter if considering a shift to the longer-wavelength side when operating at high temperature). For this reason, the semiconductor laser of the present embodiment sets the Al composition of the barrier layers 2B to be not less than 0.136.

Within the above range, characteristics of the semiconductor laser least deteriorate through operation at high temperature when the composition of the barrier layer is the composition showing the shortest wavelength. It is therefore sufficient that, for example, the compositional ratio of the barrier layers 2B is set to be Al_{0.275}Ga_{0.198}In_{0.523}As so that compositional wavelength of the barrier layers 2B is set to be 1070 nm. Here, the compositional ratio of the barrier layers 2B is set to have a lattice match for an InP substrate.

The buried-heterostructure semiconductor laser of the present embodiment can advantageously realize a 1.3-μm wavelength band semiconductor laser which avoids deterioration of light output in accordance with increase in drive current.

Here, FIG. 6 shows light output characteristics of the buried-heterostructure semiconductor laser with respect to the driving current when the compositional wavelength of the barrier layers 2B is set to be 1100 nm and 1000 nm.

As shown in FIG. 6, comparing with the light output characteristic of the buried-heterostructure semiconductor laser against the drive current at the compositional wavelength of the barrier layers 2B of 1000 nm, the light output at the compositional wavelength of 1100 nm indicates that deterioration of light output is suppressed at the compositional wavelength of 1100 nm.

### (b) Second Embodiment

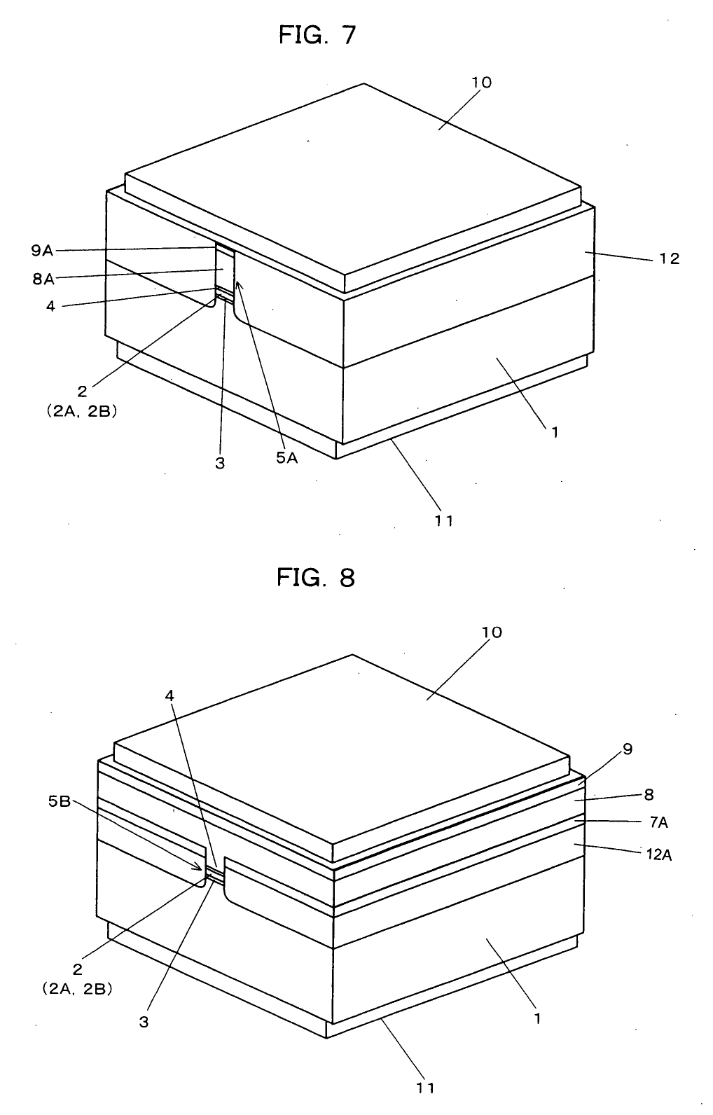

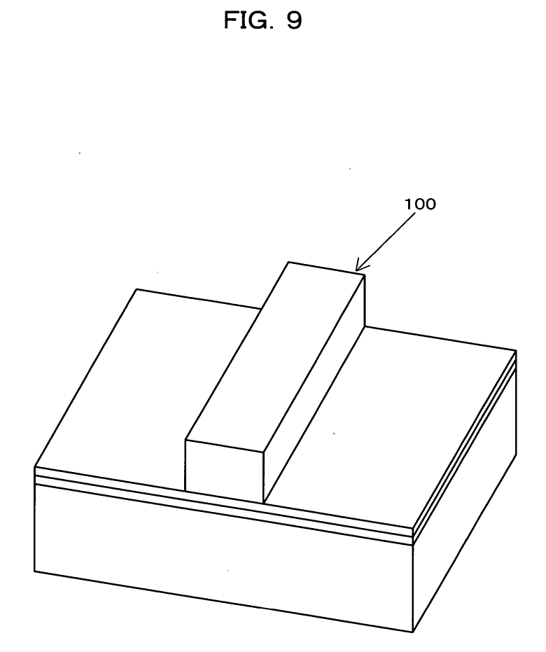

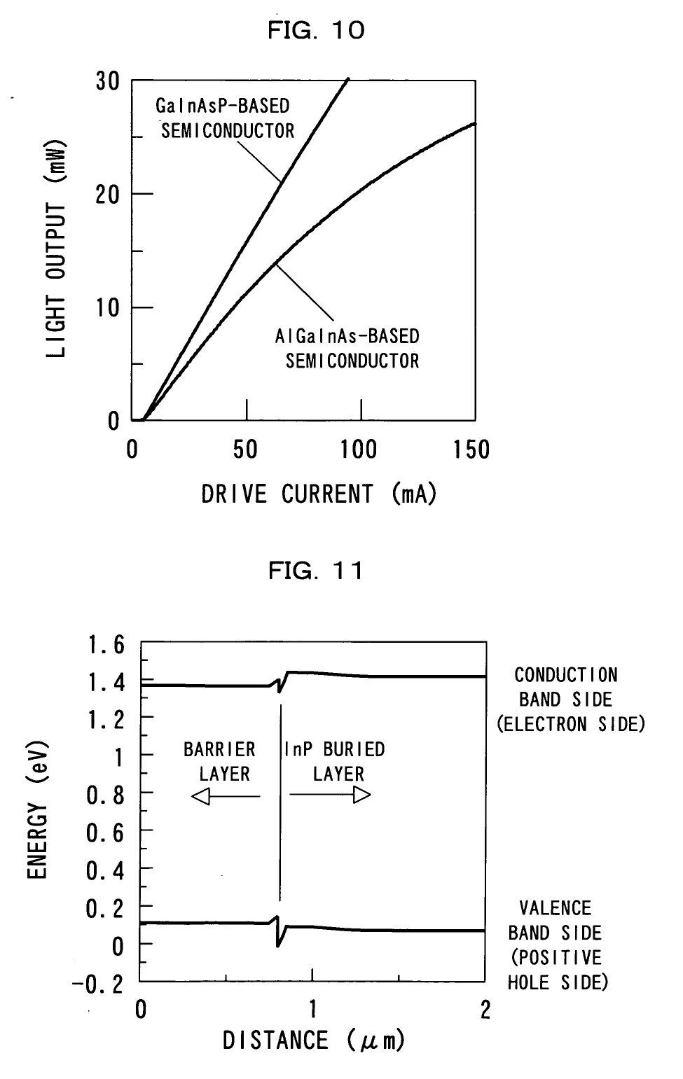

A buried-heterostructure semiconductor laser according to the second embodiment of the present invention will now be described with reference to FIG. 7.

The buried-heterostructure semiconductor laser of the second embodiment is different in a current blocking structure from that of the first embodiment.

In other words, the semiconductor laser of the second embodiment is a 1.3-μm wavelength band buried-heterostructure semiconductor laser (with an emission light wavelength of 1260-1340 nm), and includes an n-doped InP substrate (a semiconductor substrate) 1, a multiple quantum well active layer 2 which is formed by stacking an undoped AlGaInAs quantum well layer 2A (respectively having a thickness of 6 nm, for example) and an undoped AlGaInAs barrier layer 2B (having a thickness of 10 nm, for example), ten times alternately, and undoped AlGaInAs light guide layers 3 and 4 (having a thickness of 20 nm, for example) which are stacked upward and downward of the multiple quantum well active layer 2, as exemplified in FIG. 7. In addition, a p-doped InP cladding layer 8A and p-doped GaInAs contact layer 9A are sequentially stacked on the upper light guide layer 4. Similar parts or elements to the first embodiment (see FIG. 1) are designated by the same reference numbers in FIG. 7.

In the buried-heterostructure semiconductor laser of the present embodiment, a mesa structure 5A which includes the multiple quantum well active layer 2, the light guide layers 3 and 4, the cladding layer 8A and the contact layer 9A is formed as shown in FIG. 7 (which assumes that the width of these layers is 1.2 μm). Further, an Fe-doped semi-insulating InP current blocking layer (a semi-insulating semiconductor layer: an InP buried layer) 12 is formed on both sides of the mesa structure 5A and on the n-doped InP substrate 1 so as to be in contact with the sides of the multiple quantum well active layer 2, the light guide layers 3 and 4, the cladding layer 8A and the contact layer 9A that form the mesa structure 5A and also so as to bury the mesa structure 5A. As a result, the buried structure is a semi-insulating buried heterostructure (SI-BH structure) which is to serve as a current blocking structure.

Further, a p-electrode 10 and an n-electrode are formed on the top and the bottom of the buried-heterostructure semiconductor laser, respectively.

Alternatively, a number of p-doped GaInAsP layers may be inserted between the p-doped InP cladding layer 8A and the p-doped GaInAs contact layer 9A. Further alternatively, the buried-heterostructure semiconductor laser may include a single AlGaInAs light guide layer formed upward or downward of the multiple quantum well active layer 2.

In particular, the semiconductor laser of the present embodiment sets the compositional wavelength of the barrier layers 2B and the light guide layers 3 and 4 (the compositional wavelength on the edge of the conduction band) to be 1070 nm. But, it is sufficient that the compositional wavelength of the barrier layers 2B and the light guide layers 3 and 4 is set to be 1070 nm or longer likewise the first embodiment. Therefore, sufficient Al composition of the barrier layers 2B and the light guide layers 3 and 4 is 0.275 or less.

The remaining configuration of the buried-heterostructure semiconductor laser of the second embodiment is identical to that of the first embodiment, so any repetitious description is omitted here.

As a result, the buried-heterostructure semiconductor laser of the present embodiment can advantageously realize a 1.3-μm wavelength band semiconductor laser that can prevent light output from deteriorating in accordance with increase in a current drive, similarly to the first embodiment.

### (c) Third Embodiment

A buried-heterostructure semiconductor laser according to the third embodiment of the present invention will now be described with reference to FIG. 8.

The buried-heterostructure semiconductor laser of the third embodiment is different in a current blocking structure from that of the first embodiment.

In other words, the semiconductor laser of the third embodiment is a 1.3-μm wavelength band buried-heterostructure semiconductor laser (with an emission light wavelength of 1260-1340 nm), and includes an n-doped InP substrate (a semiconductor substrate) 1, a multiple quantum well active layer 2 which is formed by stacking an undoped AlGaInAs quantum well layer 2A (respectively having a thickness of 6 nm, for example) and an undoped AlGaInAs barrier layer 2B (having a thickness of 10 nm, for example), ten times alternately, and undoped AlGaInAs light guide layers 3 and 4 (having a thickness of 20 nm, for example) which are stacked upward and downward of the multiple quantum well active layer 2, as exemplified in FIG. 8. Similar parts or elements to the first embodiment (see FIG. 1) are designated by the same reference numbers in FIG. 8.

In the buried-heterostructure semiconductor laser of the present embodiment, a mesa structure 5B which includes the multiple quantum well active layer 2 and the light guide layers 3 and 4 is formed as shown in FIG. 8 (which assumes that the width of these layers is 1.2 μm). Further, an Fe-doped semi-insulating InP current blocking layer (a semi-insulating semiconductor layer: an InP buried layer) 12A and an n-doped InP current blocking layer (an InP buried layer) 7A are formed on both sides of the mesa structure 5B and on the n-doped InP substrate 1 so as to be in contact with the sides of the multiple quantum well active layer 2, and the light guide layers 3 and 4 that form the mesa structure 5B and also so as to bury the mesa structure 5B. As a result, the buried-heterostructure semiconductor laser of the present embodiment forms a semi-insulating planer buried heterostructure (SH-PBH structure), in which a part of the buried structure takes the form of a semi-insulating semiconductor layer 12A, to serve as a current blocking layer. In addition, a p-doped InP cladding layer 8 and a p-doped GaInAs contact layer 9 are sequentially stacked on the upper light guide layer 4 and the n-doped InP current blocking layer 7A.

Further, a p-electrode 10 and an n-electrode are formed on the top and the bottom of the buried-heterostructure semiconductor laser, respectively.

Alternatively, a number of p-doped GaInAsP layers may be inserted between the p-doped InP cladding layer 8 and the p-doped GaInAs contact layer 9. Further alternatively, the buried-heterostructure semiconductor laser may include a single AlGaInAs light guide layer formed upward or downward of the multiple quantum well active layer 2.

In particular, the semiconductor laser of the present embodiment sets the compositional wavelength of the barrier layers 2B and the light guide layers 3 and 4 (the compositional wavelength on the edge of the conduction band) to be 1070 nm. However, it is sufficient that the compositional wavelength of the barrier layers 2B and the light guide layers 3 and 4 is set to be 1070 nm or longer likewise the first embodiment. Therefore, sufficient Al composition of the barrier layers 2B and the light guide layers 3 and 4 is 0.275 or less.

The remaining configuration of the buried-heterostructure semiconductor laser of the third embodiment is identical to that of the first embodiment, so any repetitious description is omitted here.

As a result, the buried-heterostructure semiconductor laser of the present embodiment can advantageously realize a 1.3-μm wavelength band semiconductor laser that can prevent light output from deteriorating while a current drive is increased, similarly to the first embodiment.

### (d) Others

In the above first through the third embodiment, the compositional wavelength of the barrier layers 2B and the light guide layers 3 and 4 is set to be 1070 nm or longer (in other words, the Al composition of the barrier layers 2B is set to be 0.275 or less) in order to sufficiently implant electrons into the quantum wells. If a buried-heterostructure semiconductor laser does not have a light guide layer, it is sufficient for the semiconductor laser that the compositional wavelength of the barrier layer is set to be 1070 nm or longer (in otherwords, the Al composition of the barrier layer is set to be 0.275 or less).

The barrier layers 2B and the light guide layers 3 and 4 of the above embodiments are AlGaInAs layers, but should by no means be limited to this. Alternatively, these layers 2B, 3 and 4 may be AlGaInAsP layers. Specifically, the barrier layers and the light guide layers maybe made from an AlGaInAsP compound semiconductor including AlGaInAs and AlGaInAsP.

Further, the first through the third embodiments assume that the barrier layers 2B and the light guide layers 3 and 4 have no strain. Alternatively, these layers may have strain.

For example, in order to make the wells deeper, the barrier layer may have tensile strain by reducing the In compositional ratio and increasing the Al compositional ratio or Ga compositional ratio. In this case, the light guide layers 3 and 4 should have tensile strain the same as or larger than the tensile strain of the barrier layer 2B. For this purpose, if tensile strain is introduced into the barrier layers by increasing an Al composition ratio, the energy level of the conduction band side (electron side) of the barrier layer rises and comes close to the energy level of the conduction band side (electron side) of the buried layer (InP buried layer). This may create a notch which results in deterioration of light output. At that time, the compositional wavelength of the barrier layers becomes shorter (i.e., the band-gap becomes wider).

When the composition of the barrier layer having the same strain amount is controlled so as to dissolve the notch, the barrier layer would have tensile strain as a result of reducing the In compositional ratio and increasing the Ga compositional ratio. In this case, the Al composition should be 0.275 or less, similarly to the above embodiments. Such reduction in the In compositional ratio and increase in the Ga compositional ratio to introduce tensile strain lowers the energy level of the conduction band side (electron side) of the barrier layer as compared with the case of the above embodiments in which the compositional wavelength is 1070 nm, so that the compositional wavelength of the barrier layer becomes longer (i.e., the band-gap becomes narrower). In otherwords, the compositional wavelength of the barrier layer is 1070 nm or longer similarly to the above embodiments.

Normally, since application of tensile strain to a well layer improves the performance thereof, an ordinary barrier layer has tensile strain. For this reason, if tensile strain is introduced into the barrier layer by reducing the Al composition even though it is hardly presumed, the Al composition becomes 0.275 or less similarly to the above embodiments, and there is no possibility of creation of a notch and resultant deterioration of light output. In this case the compositional wavelength of the barrier layer becomes 1070 nm or longer.

As a result of control of the composition (of the barrier layer) so as not to create a notch, considering a relative relationship between the energy level of the conduction side (electron side) of the barrier layer and the energy level of the conduction side (electron side) of the InP buried layer, the Al composition ratio would be 0.275 or less irrespective of the presence and the absence of strain in the barrier layer. As a consequence, the compositional wavelength becomes 1070 nm or longer.

In the above first through third embodiments, the barrier layer is made from a four element semiconductor material AlGaInAs but may alternatively be made from a five element semiconductor material such as AlGaInAsP. In this case, As is reduced to incorporate P into the material. But, with the intention that a barrier layer made from AlGaInAsP material has the same strain (including no strain) and the same energy-level relationship (the same energy-band relationship as the barrier layer 2B made from AlGaInAs, the In compositional ratio should be increased and the Al compositional ratio should be reduced) because of the relationship with respect to the InP substrate and InP buried layer. In other words, the Al compositional ratio is set to be 0.275 or less likewise the foregoing embodiments.

As mentioned above, by setting the Al compositional ratio to be 0.275 or less irrespective of ratios As and P (at any As/P ratio), the compositional wavelength of the barrier layer becomes 1070 nm or longer.

Further, the quantum well layer 2A in the foregoing embodiments is an AlGaInAs quantum well layer, but should by no means be limited to this. Alternatively, the quantum well layer 2A may be made from an AlGaInAsP compound semiconductor including AlGaInAs and AlGaInAsP. Further, the quantum well layer may be a GaInAsP quantum well layer or a GaInAs quantum well layer. In other words, an AlGaInAsP group compound semiconductor including AlGaInAsP and AlGaInAs may form a quantum well layer.

In addition, the buried layer of the above embodiments is an InP buried layer because the InP layer good fine heat resistance and can be grown on the InP substrate. But, the buried layer should by no means be limited to this. Any material can be used as the buried layer as long as the material has capability of lattice matching for the InP substrate and has a wider band-gap than those of barrier layers and light guide layers. For example, the buried layer may be an InGaAsP buried layer or an InAlAs buried layer.

Still further, the buried-heterostructure semiconductor laser of the first through the third embodiments is formed on the n-doped InP substrate having n-type conductivity, but should by no means be limited to this. For example, the buried-heterostructure semiconductor laser may be formed on a substrate having p-type conductivity. In this case, layers stacked on the semiconductor substrate have the opposite conductivity to that of the substrate. Further alternatively, the buried-heterostructure semiconductor laser of the present invention may be formed on a semi-insulating substrate or may be formed by binding layers onto a silicon substrate.

Further, the present invention should by no means be limited to these foregoing embodiments, and various changes or modifications may be suggested without departing from the gist of the invention.

1. A 1.3-μm wavelength band buried-heterostructure semiconductor laser, comprising:
a semiconductor substrate;
a multiple quantum well active layer including quantum well layers and barrier layers; and
a buried layer in contact with side faces of said multiple quantum well active layer, wherein
said barrier layers are made from AlGaInAsP, and
an Al composition of said barrier layers is 0.275 or less.

2. A 1.3-μm wavelength band buried-heterostructure semiconductor laser according to claim 1, further comprising a light guide layer formed above or below said multiple quantum well active layer, wherein
said light guide layer is made from AlGaInAsP and an Al composition of said light guide layer is 0.275 or less.

3. A 1.3-μm wavelength band buried-heterostructure semiconductor laser according to claim 1, wherein an Al composition of said barrier layers is 0.136 or more.

4. A 1.3-μm wavelength band buried-heterostructure semiconductor laser according to claim 2, wherein an Al composition of said barrier layer is 0.136 or more.

5. A 1.3-μm wavelength band buried-heterostructure semiconductor laser according to claim 1, wherein said buried layer is an InP buried layer made from InP.

6. A 1.3-μm wavelength band buried-heterostructure semiconductor laser according to claim 1, wherein said buried layer forms a pnpn thyristor structure.

7. A 1.3-μm wavelength band buried-heterostructure semiconductor laser according to claim 1, wherein said buried layer includes a semi-insulating semiconductor layer, and forms a semi-insulating planar buried heterostructure.

8. A 1.3-μm wavelength band buried-heterostructure semiconductor laser according to claim 1, wherein said buried layer is made from a semi-insulating semiconductor layer, and forms a semi-insulating buried heterostructure.

9. A 1.3-μm wavelength band buried-heterostructure semiconductor laser according to claim 1, wherein said multiple quantum well active layer is made from a compound selected from a group consisting of AlGaInAsP, AlGaInAs, GaInAs, and GaInAs.

10. A 1.3-μm wavelength band buried semiconductor laser according to claim 1, wherein said multiple quantum well active layer is a nonstrained multiple quantum well active layer.

11. A 1.3-μm wavelength band buried-heterostructure semiconductor laser according to claim 1, wherein:
said barrier layers have tensile strain; and
said multiple quantum well active layer has compressed strain.

12. A 1.3-μm wavelength band buried-heterostructure semiconductor laser, comprising:
a semiconductor substrate;
a multiple quantum well active layer including quantum well layers and barrier layers; and
a buried layer in contact with side faces of said multiple quantum well active layer, wherein
said barrier layers are made from AlGaInAsP or AlGaInAs, and
an Al composition of said barrier layers is 0.225 or more and 0.275 or less.

13. A 1.3-μm wavelength band buried-heterostructure semiconductor laser according to claim 1, further comprising a light guide layer formed upwards or downwards of said multiple quantum well active layer, wherein
said light guide layer is made from AlGaInAsP or AlGaInAs and an Al composition of said light guide layer is 0.225 or more and 0.275 or less.
